(19) United States
(12) Patent Application Publication
(10) Pub. No.: US 2024/0260405 A1
(43) Pub. Date: Aug. 1, 2024

(54) DISPLAY DEVICE AND METHOD OF MANUFACTURING THE SAME

(71) Applicant: Samsung Display Co., LTD., Yongin-si, Gyeonggi-do (KR)

(72) Inventors: SUNGMIN HUR, Yongin-si (KR); JUNGHAN SEO, Yongin-si (KR)

(21) Appl. No.: 18/497,485

(22) Filed: Oct. 30, 2023

(30) Foreign Application Priority Data
Jan. 30, 2023 (KR) 10-2023-0011737

(51) Int. Cl. H10K 59/80; H10K 59/12

(52) U.S. Cl. CPC H10K 59/873; H10K 59/1201

(57) ABSTRACT

A display device includes a substrate, a light-emitting layer disposed on the substrate, a first inorganic layer disposed on the light-emitting layer, an organic layer disposed on the first inorganic layer, a second inorganic layer disposed on the organic layer, where the second inorganic layer has a film density of about 1.7 grams per cubic centimeter (g/cm³) or greater and about 1.9 grams per cubic centimeter (g/cm³) or less, and a refractive index of about 1.85 or greater and about 1.86 or less, and a third inorganic layer disposed on the second inorganic layer.

This application claims priority to Korean Patent Application No. 10-2023-0011737, filed on Jan. 30, 2023, and all the benefits accruing therefrom under 35 U.S.C. § 119, the content of which in its entirety is herein incorporated by reference.

### BACKGROUND

### 1. Field

Embodiments relate to a display device. More particularly, a display device and a method of manufacturing the display device.

### 2. Description of the Related Art

A display device includes a light-emitting element and an encapsulation layer. The encapsulation layer may protect the light-emitting element from external moisture and oxygen by sealing the light-emitting element.

The encapsulation layer may include an inorganic layer. Accordingly, the encapsulation layer may have barrier properties (e.g., a property of protecting the light-emitting element from external moisture or oxygen). In addition, the encapsulation layer may include an organic layer. Accordingly, the encapsulation layer may have a flat top surface.

### SUMMARY

In a display device including an encapsulation layer, when a thickness of the inorganic layer is reduced to reduce a thickness of the display device, the barrier properties of the encapsulation layer may deteriorate. On the other hand, when the thickness of the inorganic layer is increased to increase the barrier properties, film stress may increase and film detachment may occur.

An embodiment provides a display device including an encapsulation layer with enhanced barrier properties.

Another embodiment provides a method of manufacturing the display device.

A display device according to an embodiment of the disclosure includes a substrate, a light-emitting layer disposed on the substrate, a first inorganic layer disposed on the light-emitting layer, an organic layer disposed on the first inorganic layer, a second inorganic layer disposed on the organic layer, wherein the second inorganic layer has a film density of about 1.7 grams per cubic centimeter (g/cm³) or greater and about 1.9 grams per cubic centimeter (g/cm³) or less, and a refractive index of about 1.85 or greater and about 1.86 or less, and a third inorganic layer disposed on the second inorganic layer.

In an embodiment, the second inorganic layer and the third inorganic layer may have different thicknesses from each other.

In an embodiment, the second inorganic layer may have a thickness of about 300 angstroms (Å) or greater and about 1000 angstroms (Å) or less.

In an embodiment, the third inorganic layer may have a thickness of about 6000 angstroms (Å) or greater and about 10000 angstroms (Å) or less.

In an embodiment, the second inorganic layer and the third inorganic layer may include a same material as each other.

In an embodiment, each of the second inorganic layer and the third inorganic layer may include silicon nitride.

In an embodiment, each of the second inorganic layer and the third inorganic layer may include silicon oxynitride.

In an embodiment, the display device may further include a first active pattern disposed on the substrate, and a second active pattern disposed on the first active pattern.

In an embodiment, the first active pattern may include a silicon semiconductor, and the second active pattern includes an oxide semiconductor.

A method of manufacturing a display device according to another embodiment of the disclosure includes forming a light-emitting layer on a substrate, forming a first inorganic layer on the light-emitting layer, forming an organic layer on the first inorganic layer, forming a second inorganic layer on the organic layer, wherein the second inorganic layer has a film density of about 1.7 grams per cubic centimeter (g/cm³) or greater and about 1.9 grams per cubic centimeter (g/cm³) or less, and a refractive index of about 1.85 or greater and about 1.86 or less, and forming a third inorganic layer on the second inorganic layer.

In an embodiment, each of the first inorganic layer, the second inorganic layer, and the third inorganic layer may be formed by a chemical vapor deposition.

In an embodiment, plasma power to form the second inorganic layer may be about 3000 watts (W) or greater and about 5000 watts (W) or less.

In an embodiment, a pressure of a chamber to form the second inorganic layer may be about 1 torr or greater and about 1.7 torr or less.

In an embodiment, the organic layer may be formed by an inkjet process.

In an embodiment, the second inorganic layer and the third inorganic layer may be formed to have different thicknesses from each other.

In an embodiment, the second inorganic layer may be formed to have a thickness of about 300 angstroms (Å) or greater and about 1000 angstroms (Å) or less.

In an embodiment, the third inorganic layer may be formed to have a thickness of about 6000 angstroms (Å) or greater and about 10000 angstroms (Å) or less.

In an embodiment, the second inorganic layer and the third inorganic layer may include a same material as each other.

In an embodiment, each of the second inorganic layer and the third inorganic layer may include silicon nitride.

In an embodiment, each of the second inorganic layer and the third inorganic layer may include silicon oxynitride.

In a display device according to embodiments of the disclosure, the display device may include the substrate, the light-emitting layer on the substrate, the first inorganic layer on the light-emitting layer, the organic layer on the first inorganic layer, the second inorganic layer on the organic layer, having the film density of about 1.7 grams per cubic centimeter (g/cm³) or greater and about 1.9 grams per cubic centimeter (g/cm³) or less, and the refractive index of about 1.85 or greater and about 1.86 or less, and the third inorganic layer on the second inorganic layer. In such an embodiment, the second inorganic layer may effectively prevent an occurrence of a spot due to a plasma treatment and may enhance a barrier property. Accordingly, an occurrence of a stain in the display device may be effectively prevented.

### BRIEF DESCRIPTION OF THE DRAWINGS

FIG. 1 is a plan view illustrating a display device according to an embodiment of the disclosure.

FIGS. 2 and 3 are cross-sectional views illustrating the display device of FIG. 1.

FIG. 4 is a view illustrating an encapsulation layer included in the display device of FIG. 1.

FIGS. 5, 6, 7, 8, and 9 are views illustrating an embodiment of a method of manufacturing the encapsulation layer of FIG. 4.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings. The same reference numerals are used for the same components in the drawings, and any repetitive detailed descriptions of the same components will be omitted or simplified.

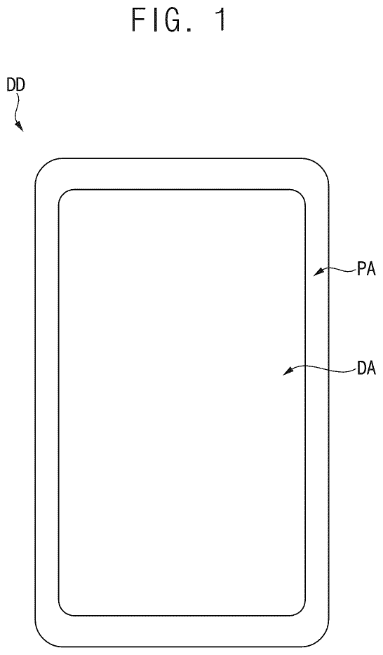

FIG. 1 is a plan view illustrating a display device according to an embodiment of the disclosure.

Referring to FIG. 1, an embodiment of a display device DD may be divided into a display area DA and a peripheral area PA.

The display area DA is an area for displaying an image, and for this purpose, a plurality of pixels may be disposed in the display area DA. Each of the plurality of pixels may be a minimum (or basic) unit that emits light. The plurality of pixels may be disposed in the display area DA as a whole.

The peripheral area PA may be positioned on at least a side of the display area DA. In an embodiment, for example, the peripheral area PA may surround the display area DA. Drivers (e.g., gate drivers and/or data drivers) may be disposed in the peripheral area PA, and electronic elements such as integrated circuits and circuit boards may be electrically connected to a display panel in the peripheral area PA.

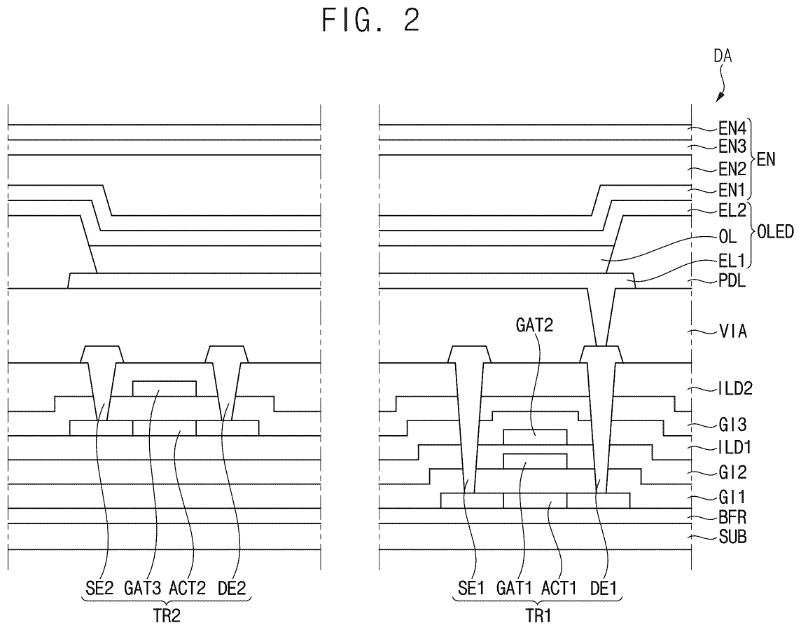

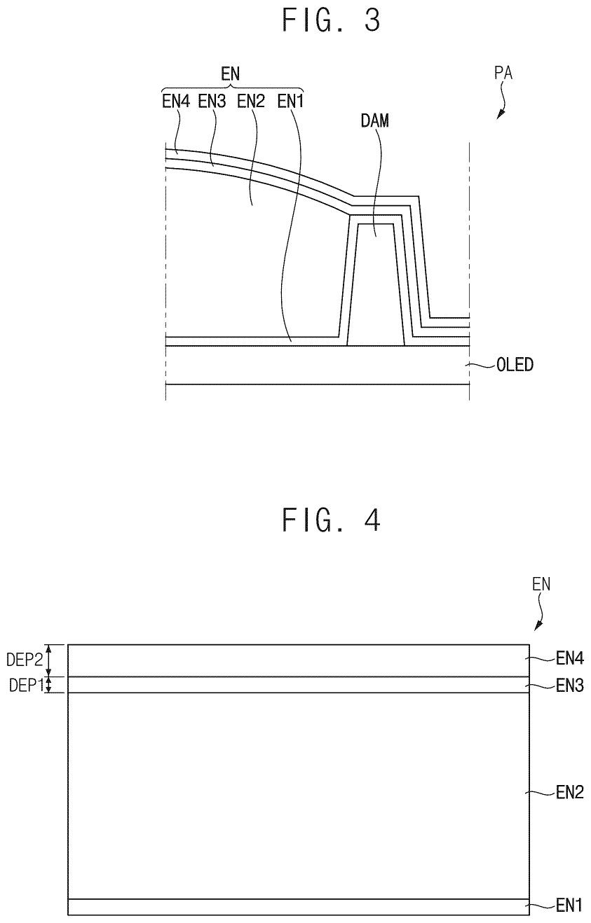

FIGS. 2 and 3 are cross-sectional views illustrating the display device of FIG. 1.

Particularly, FIG. 2 is a cross-sectional view illustrating a portion of the display area DA of the display device DD, and FIG. 3 is a cross-sectional view illustrating a portion of each non-display area PA of the display device DD.

Referring to FIGS. 1, 2, and 3, an embodiment of the display device DD may include a substrate SUB, a buffer layer BFR, a first transistor TR1, a first gate insulating layer GI1, a second gate insulating layer GI2, a first interlayer insulating layer ILD1, a second transistor TR2, a third gate insulating layer GI3, a second interlayer insulating layer ILD2, a via insulating layer VIA, a pixel defining layer PDL, a light-emitting element OLED, an encapsulation layer EN, and a dam DAM.

The first transistor TR1, the second transistor TR2, and the light-emitting element OLED may be disposed in the display area DA. The dam DAM may be disposed in the peripheral area PA.

The first transistor TR1 may include a first active pattern ACT1, a first gate electrode GAT1, a first source electrode SE1 and a first drain electrode DE1, and the second transistor TR2 may include a second active pattern ACT2, a third gate electrode GAT3, a second source electrode SE2, and a second drain electrode DE2, and the light-emitting element OLED may include a first electrode EL1, a light-emitting layer OL, and a second electrode EL2.

The substrate SUB may include glass, quartz, plastic, or the like. In an embodiment, the substrate SUB may have flexible, bendable, or rollable characteristics.

The buffer layer BFR may be disposed on the substrate SUB. The buffer layer BFR may include an inorganic insulating material. In an embodiment, for example, the buffer layer BFR may include silicon oxide, silicon nitride, silicon oxynitride, or the like. These may be used alone or in combination with each other. The buffer layer BFR may block impurities so that the first active pattern ACT1 of the transistors (e.g., the first transistor TR1) may be effective prevented from being damaged by the impurities diffused from the substrate SUB. In addition, the buffer layer BFR may control a heat supply rate during a crystallization process for forming the first active pattern ACT1. Accordingly, the first active pattern ACT1 may be formed relatively uniformly or to have a substantially constant thickness.

In an alternative embodiment, the buffer layer BFR may be omitted depending on a type of the substrate SUB and process conditions.

The first active pattern ACT1 may be disposed on the buffer layer BFR. In an embodiment, the first active pattern ACT1 may include a silicon semiconductor material. In an embodiment, for example, the first active pattern ACT1 may include amorphous silicon, polycrystalline silicon, or the like. These may be used alone or in combination with each other. The first active pattern ACT1 may include a source region, a drain region, and a channel region positioned between the source region and the drain region.

The first gate insulating layer GI1 may be disposed on the first active pattern ACT1. The first gate insulating layer GI1 may include an inorganic insulating material. In an embodiment, for example, the first gate insulating layer GI1 may include silicon oxide, silicon nitride, silicon oxynitride, titanium oxide, tantalum oxide, or the like. These may be used alone or in combination with each other. The first gate insulating layer GI1 may electrically insulate the first active pattern ACT1 and the first gate electrode GAT1 from each other.

The first gate electrode GAT1 may be disposed on the first gate insulating layer GI1. The first gate electrode GAT1 may include a conductive material. In an embodiment, for example, the first gate electrode GAT1 may include a metal, an alloy, a conductive metal oxide, a transparent conductive material, or the like. These may be used alone or in combination with each other.

The second gate insulating layer GI2 may be disposed on the first gate electrode GAT1. The second gate insulating layer GI2 may include an inorganic insulating material. The second gate insulating layer GI2 may electrically insulate the first gate electrode GAT1 and the second gate electrode GAT2 from each other.

The second gate electrode GAT2 may be disposed on the second gate insulating layer GI2. The second gate electrode GAT2 may include a conductive material.

The first interlayer insulating layer ILD1 may be disposed on the second gate electrode GAT2. The first interlayer insulating layer ILD1 may include an organic insulating material and/or the inorganic insulating material. In an embodiment, for example, the first interlayer insulating layer ILD1 may include a same material as the gate insulating layers (e.g., the first gate insulating layer GI1 and the second gate insulating layer GI2). The first interlayer insulating layer ILD1 may function as a buffer for the second transistor TR2 to be described later.

In an embodiment, the second active pattern ACT2 and the first active pattern ACT1 may be disposed in (or directly on) different layers from each other. In an embodiment, the second active pattern ACT2 may be disposed on the first interlayer insulating layer ILD1.

In an embodiment, the second active pattern ACT2 and the first active pattern ACT1 may include different materials from each other. In an embodiment, the second active pattern ACT2 may include an oxide semiconductor material. In an embodiment, for example, the second active pattern ACT2 may include zinc oxide, zinc-tin oxide, zinc-indium oxide, indium oxide, titanium oxide, indium-gallium-zinc oxide, indium-zinc-tin oxide, or the like. These may be used alone or in combination with each other. The second active pattern ACT2 may include a source region, a drain region, and a channel region positioned between the source region and the drain region.

The third gate insulating layer GI3 may be disposed on the second active pattern ACT2. The third gate insulating layer GI3 may include an inorganic insulating material. The third gate insulating layer GI3 may electrically insulate the second active pattern ACT2 and the second gate electrode GAT2 from each other.

The third gate electrode GAT3 may be disposed on the third gate insulating layer GI3. The third gate electrode GAT3 may include a conductive material.

The second interlayer insulating layer ILD2 may be disposed on the third gate electrode GAT3. The second interlayer insulating layer ILD2 may include a same material as the gate insulating layers (e.g., the first gate insulating layer GI1, the second gate insulating layer GI2, and the third gate insulating layer GI3). The second interlayer insulating layer ILD2 may electrically insulate the first source electrode SE1 and the first drain electrode DE1 from the third gate electrode GAT3.

The source electrodes SE1 and SE2 and the drain electrodes DE1 and DE2 may be disposed on the second interlayer insulating layer ILD2. Each of the first source electrode SE1 and the first drain electrode DE1 may be electrically connected to the first active pattern ACT1 through a contact hole defined (or formed) through the second interlayer insulating layer ILD2, the third gate insulating layer GI3, the first interlayer insulating layer ILD1, the second gate insulating layer GI2, and the first gate insulating layer GI1. Each of the second source electrode SE2 and the second drain electrode DE2 can be electrically connected to the second active pattern ACT2 through a contact hole defined through the second interlayer insulating layer ILD2 and the third gate insulating layer GI3.

Each of the source electrodes SE1 and SE2 and the drain electrodes DE1 and DE2 may include a conductive material. In an embodiment, for example, each of the source electrodes SE1 and SE2 and the drain electrodes DE1 and DE2 may include a metal, an alloy, a conductive metal oxide, a transparent conductive material, or the like. These may be used alone or in combination with each other.

The via insulating layer VIA may be disposed on the source electrodes SE1 and SE2 and the drain electrodes DE1 and DE2. The via insulating layer VIA may include an organic insulating material. In an embodiment, for example, the via insulating layer VIA may include polyacrylate resin, epoxy resin, phenolic resin, polyamides resin, polyimide resin., unsaturated polyesters resin, polyphenylene ethers resin, polyphenylene sulfides resin, benzocyclobutene (BCB), or the like. These may be used alone or in combination with each other. Accordingly, a top surface of the via insulating layer VIA may be substantially flat.

The first electrode EL1 may be disposed on the via insulating layer VIA. The first electrode EL1 may be electrically connected to the source electrodes SE1 and SE2 or the drain electrodes DE1 and DE2 through a contact hole defined through the via insulating layer VIA. In an embodiment, the first electrode EL1 may be referred to as an anode electrode.

The first electrode EL1 may include a conductive material. In an embodiment, for example, the first electrode EL1 may include a metal, an alloy, a metal oxide, a transparent conductive material, or the like. In an embodiment, for example, the first electrode EL1 may include aluminum, an alloy including aluminum, aluminum nitride, silver, an alloy including silver, tungsten, tungsten nitride, copper, an alloy including copper, nickel, chromium, chromium nitride, molybdenum, alloys including molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, or the like. These may be used alone or in combination with each other.

The pixel defining layer PDL may be disposed on the first electrode EL1. The pixel defining layer PDL may include an organic insulating material. In an embodiment, for example, the pixel defining layer PDL may include polyacrylate resin, polyimide resin, or the like. These may be used alone or in combination with each other. The pixel defining layer PDL may partition each of light-emitting area of the plurality of pixels. In an embodiment, a pixel opening exposing the first electrode EL1 may be defined through the pixel defining layer PDL.

The light-emitting layer OL may be disposed on the first electrode EL1 in the pixel opening. The light-emitting layer OL may include an organic light-emitting material. In an embodiment, the light-emitting layer OL may have a multi-layer structure including various functional layers. In an embodiment, for example, the light-emitting layer OL may further include at least one of a hole injection layer (HIL), a hole transport layer (HTL), an electron transport layer (ETL), and an electron injection layer (EIL).

The second electrode EL2 may be disposed on the light-emitting layer OL and may cover the pixel defining layer PDL. In an embodiment, the second electrode EL2 may be referred to as a cathode electrode.

The second electrode EL2 may include a metal, an alloy, a metal oxide, a transparent conductive material, or the like. In an embodiment, for example, the second electrode EL2 may include aluminum, an alloy including aluminum, aluminum nitride, silver, an alloy including silver, tungsten, tungsten nitride, copper, an alloy including copper, nickel, chromium, chromium nitride, molybdenum, alloys including molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, or the like. These may be used alone or in combination with each other.

The encapsulation layer EN may be disposed on the second electrode EL2. The encapsulation layer EN may block moisture and oxygen inflow from an outside. The encapsulation layer EN may include at least an inorganic layer and at least an organic layer.

In an embodiment, the encapsulation layer EN may include a first inorganic layer EN1, an organic layer EN2, a second inorganic layer EN3, and a third inorganic layer EN4. The first inorganic layer EN1 may be disposed on the light-emitting element OLED. The organic layer EN2 may be disposed on the first inorganic layer EN1. The organic layer EN2 may be disposed on the organic layer EN2. The third inorganic layer EN4 may be disposed on the organic layer EN2. Detailed features of the encapsulation layer EN will be described later with reference to FIG. 4.

The dam DAM may be disposed in the peripheral area PA. The dam DAM may include a material included in the pixel defining layer PDL and/or a material included in the via insulating layer VIA. The dam DAM may block the organic layer EN2.

In an embodiment, the peripheral area PA may be covered only with the inorganic layers (e.g., the first inorganic layer EN1, the organic layer EN2, and the third inorganic layer EN4) having excellent barrier properties. In such an embodiment, in the peripheral area PA, the first inorganic layer EN1 and the organic layer EN2 may directly contact each other. In an embodiment, an ashing process may be performed to remove a portion of the organic layer EN2 overlapping the peripheral area PA before the organic layer EN2 is formed. A stable encapsulation layer EN may be formed by preventing the organic layer EN2 having low moisture permeability from being exposed to the outside.

However, the disclosure is not limited thereto. In an alternative embodiment, for example, the display device DD may further include a capping layer and a protective layer disposed on the second electrode EL2.

The capping layer may be disposed on the second electrode EL2. The capping layer may include an organic material. In an embodiment, for example, the capping layer may include a-NPD, NPB, TPD, m-MTDATA, Alq3, CuPc, or the like. These may be used alone or in combination with each other. The capping layer may protect the light-emitting element OLED and guide light emitted from the light-emitting layer OL.

The protective layer may be disposed on the capping layer. In an embodiment, for example, the protective layer may include LiF, MgF2, CaF, or the like. These may be used alone or in combination with each other. The protective layer may prevent plasma or the like from penetrating the light-emitting element OLED and causing damage in a process of forming the first inorganic layer EN1.

FIG. 4 is a view illustrating an encapsulation layer included in the display device of FIG. 1.

Referring to FIG. 4, an embodiment of the encapsulation layer EN may include the first inorganic layer EN1, the organic layer EN2, the second inorganic layer EN3, and the third inorganic layer EN4.

The first inorganic layer EN1 may be disposed on the light-emitting element OLED. The first inorganic layer EN1 may include an inorganic material. In an embodiment, the first inorganic layer EN1 may include a silicon compound. In an embodiment, for example, the first inorganic layer EN1 may include silicon oxynitride (SiON). The silicon oxynitride may have higher transmittance compared to silicon nitride (SiN) described later.

The organic layer EN2 may be disposed on the first inorganic layer EN1. In an embodiment, the organic layer EN2 may include an organic insulating material. In such an embodiment, the organic layer EN2 may have a substantially flat top surface.

The second inorganic layer EN3 may be disposed on the organic layer EN2. In an embodiment, the second inorganic layer EN3 may include a silicon compound. In an embodiment, for example, the second inorganic layer EN3 may include silicon nitride (SiN). The silicon nitride may have higher mechanical strength and higher barrier properties than the silicon oxynitride.

In an embodiment, where the second inorganic layer EN3 may be formed by using a chemical vapor deposition (CVD) method, components disposed under the second inorganic layer EN3 (e.g., the organic layer EN2) may be formed by setting a radio-frequency (RF) power relatively low to prevent damage thereto.

In an embodiment, the RF power may be in a range of about 3000 watts (W) to about 5000 W, that is, be about 3000 W or greater and about 5000 W or less. If the RF power is less than about 3000 W, silicon nitride grains included in the second inorganic layer EN3 might not be reached an energy-stable state when the silicon nitride grains grow. Accordingly, the grain size of the silicon nitride may be formed to be relatively large, and the generation of voids may increase, so that barrier properties may be weakened. On the other hand, if the RF power exceeds about 5000 W, the second inorganic layer EN3 may be damaged by the plasma.

In an embodiment, the second inorganic layer EN3 may have a dense film quality to have the barrier properties.

In an embodiment, a film density of the second inorganic layer EN3 may be in a range of about 1.7 grams per cubic centimeter (g/cm³) to about 1.9 g/cm³. The film density of the second inorganic layer EN3 may be confirmed or determined by X-ray reflectometry (XRR). If the film density of the second inorganic layer EN3 is less than about 1.7 g/cm³, the barrier properties may be weakened. On the other hand, if the film density of the second inorganic layer EN3 exceeds about 1.9 g/cm³, optical properties of the encapsulation layer EN may be changed by changing a refractive index of the second inorganic layer EN3.

In an embodiment, a first thickness DEP1 of the second inorganic layer EN3 may be in a range of about 300 angstroms (Å) to about 1000 Å. The first thickness DEP1 of the second inorganic layer EN3 may be confirmed or determined by the X-ray reflectometry (XRR). If the first thickness DEP1 of the second inorganic layer EN3 is less than about 300 A, components disposed under the second inorganic layer EN3 may be damaged by plasma. On the other hand, if the first thickness DEP1 of the second inorganic layer EN3 exceeds about 1000 Å, the second inorganic layer EN3 may be peeled off due to an increase in film stress.

In an embodiment, the refractive index of the second inorganic layer EN3 may be in a range of about 1.85 to about 1.86. The refractive index of the second inorganic layer EN3 may be confirmed by ellipsometry. Accordingly, optical characteristics of the encapsulation layer EN might not change. In an embodiment, for example, the optical characteristics of the encapsulation layer EN may mean transmittance. In such an embodiment where the refractive index of the second inorganic layer EN3 satisfies the aforementioned range, light emitted from the light-emitting element OLED may be transmitted without being absorbed by the second inorganic layer EN3.

The third inorganic layer EN4 may be disposed on the second inorganic layer EN3. In an embodiment, the third inorganic layer EN4 may include a same material as the second inorganic layer EN3. In an embodiment, for example, the third inorganic layer EN4 may include silicon nitride (SiN). However, the configuration of the disclosure is not limited thereto, and alternatively, the third inorganic layer EN4 may include a silicon compound different from that of the second inorganic layer EN3.

In an embodiment, the third inorganic layer EN4 may be formed with a relatively higher RF power than the second inorganic layer EN3. In an embodiment, for example, the RF power for forming the third inorganic layer EN4 may exceed about 5000 W. Accordingly, an occurrence of the voids in the display device may be reduced, and barrier properties of the display device may be further enhanced.

In an embodiment, the third inorganic layer EN4 may have a thickness different from that of the second inorganic layer EN3. In an embodiment, for example, the third inorganic layer EN4 may have a second thickness DEP2 in a range of about 6000 Å to about 10000 Å to enhance the barrier properties and mechanical strength. If the second thickness DEP2 is less than about 6000 Å, components disposed under the third inorganic layer EN4 (e.g., the second inorganic layer EN3) may be damaged by the plasma. On the other hand, if the second thickness DEP2 exceeds about 10000 Å, the third inorganic layer EN4 may be peeled due to the increase in film stress.

Hereinafter, features of the encapsulation layer according to a comparative embodiment and the encapsulation layer according to an embodiment of the disclosure will be described.

The encapsulation layer EN included in the display device according to the embodiment of the disclosure, the first inorganic layer EN1 include or is formed of silicon oxynitride, the organic layer EN2 include or is formed of a monomer, and both the second inorganic layer EN3 and the third inorganic layer EN4 include or are formed of silicon nitride. The film density of the second inorganic layer EN3 according to the embodiment of the disclosure is about 1.84 g/cm³, and the refractive index of the second inorganic layer EN3 is about 1.853.

The encapsulation layer included in the display device according to the comparative embodiment is formed in a same structure as the encapsulation layer EN included in the display device according to the embodiment of the disclosure, however, a film density is different from the film density of the second inorganic layer EN3. The film density of the second inorganic layer according to the comparative embodiment is about 1.66 g/cm³, and the refractive index of the second inorganic layer is about 1.85.

Referring to “Table 1” below, the display devices according to the embodiment of the disclosure and the comparative embodiment are exposed to about 85 degrees Celsius and about 85% humidity for 96 hours, 168 hours, and 336 hours.

TABLE 1

| time (h) | 96 | 168 | 336 |
|---|---|---|---|
| comparative embodiment | 2.7 | 6.7 | 11.5 |
| embodiment of the disclosure | 0 | 0 | 1 |

As shown in Table 1, in a case of the display device according to the embodiment, after about 336 hours, about 1 stain was generated per glass.

On the other hand, in a case of the display device according to the comparative embodiment, after about 96 hours, about 2.7 stains are generated per glass, and after about 168 hours, about 6.7 stains are generated per glass, and about 336 hours, about 11.5 stains are generated per glass.

The display device according to the embodiment of the disclosure may have a denser film quality (i.e., higher film density) than the display device according to the comparative embodiment. The display device according to the comparative embodiment may have substantially the same or similar refractive index of the display device according to the comparative embodiment. The display device according to the comparative embodiment may have more enhanced barrier characteristics than the display device according to the comparative embodiment without a substantial change in display quality.

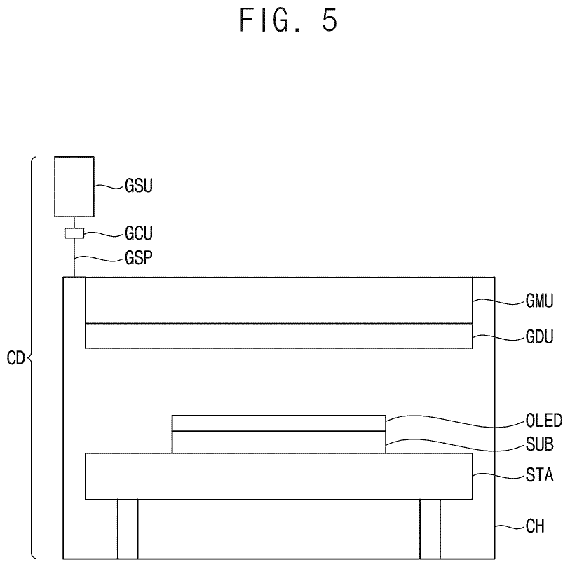

FIGS. 5, 6, 7, 8, and 9 are views illustrating an embodiment of a method of manufacturing the encapsulation layer of FIG. 4.

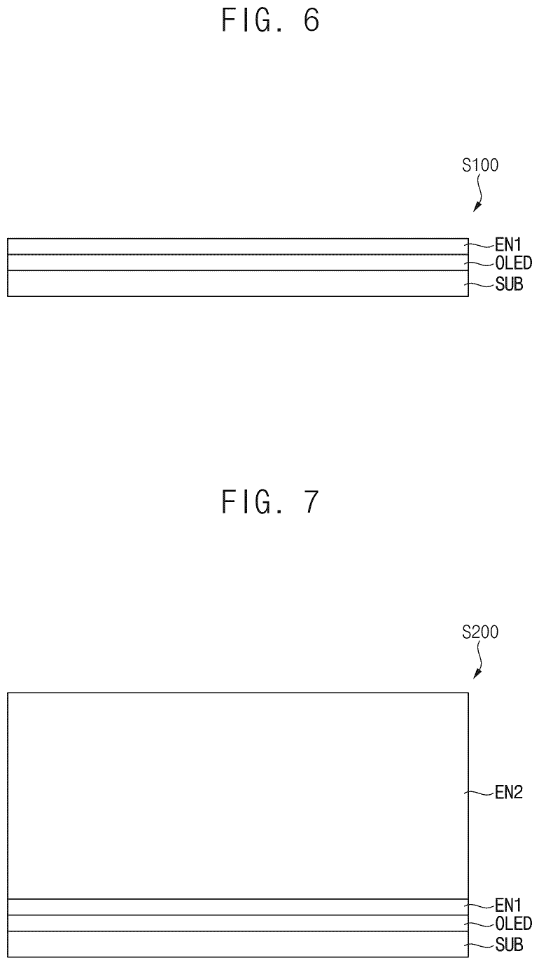

Particularly, FIG. 5 is a cross-sectional view of a deposition device CD for manufacturing the encapsulation layer EN of FIG. 4. FIGS. 6, 7, 8, and 9 are cross-sectional views illustrating the method of manufacturing the encapsulation layer EN. Hereinafter, any repetitive detailed description of the same or like elements as those of the display device DD described above with reference to FIGS. 1, 2, 3, and 4 will be omitted or simplified.

FIGS. 4 and 5, an embodiment of the deposition device CD may include a chamber CH, a stage STA, a gas supplier GSU, a gas controller GCU, a gas supply pipe GSP, a gas mixer GMU, and a gas injector GDU. In an embodiment, for example, the deposition device CD may be a plasma-enhanced chemical vapor deposition (PECVD) device.

The stage STA, the gas mixer GMU, and the gas injector GDU may be disposed inside the chamber CH. The gas supplier GSU, the gas controller GCU, and the gas supply pipe GSP may be disposed outside the chamber CH.

The stage STA may support an object to be processed (e.g., the substrate SUB on which the light-emitting element OLED is formed). In such an embodiment, the object to be processed may be disposed on the stage STA.

The gas supplier GSU may store gas. The gas supplier GSU may be provided in plural. Each of the plurality of gas supplier GSU may store a plurality of reaction gases. In an embodiment, for example, the gas supplier GSU may store SiH₄ gas, NH₃ gas, N₂O gas, N₂ gas, H₂ gas, or the like.

The gas supplier GSU may be connected to the chamber CH through the gas supply pipe GSP. In an embodiment, for example, the gas supplier GSU may supply the reaction gases into the chamber CH through the gas supply pipe GSP.

A gas controller GCU may be connected to the gas supply pipe GSP. The gas controller GCU may control a flow rate of the reaction gases introduced into the chamber CH.

The gas mixer GMU may mix the reaction gases supplied by the gas supplier GSU.

The gas injector GDU may inject the reaction gases mixed in the gas mixer GMU toward the stage STA.

A plasma gas may exist on the gas injector GDU and the stage STA. The mixed reaction gases may pass through the plasma gas to form the encapsulation layer EN.

The encapsulation layer EN may include the first inorganic layer EN1, the organic layer EN2, the second inorganic layer EN3, and the third inorganic layer EN4. Process conditions may be changed for each process of forming the first inorganic layer EN1, the organic layer EN2, the second inorganic layer EN3, and the third inorganic layer EN4. In an embodiment, for example, for each process of the forming of the first inorganic layer EN1, the organic layer EN2, the second inorganic layer EN3, and the third inorganic layer EN4, the RF (radio frequency), an internal pressure of the chamber CH, or the like may be changed.

In an embodiment, each of the first inorganic layer EN1, the organic layer EN2, the second inorganic layer EN3, and the third inorganic layer EN4 may be sequentially formed in a same chamber CH. Alternatively, each of the first inorganic layer EN1, the organic layer EN2, the second inorganic layer EN3, and the third inorganic layer EN4 may be formed in different chambers, respectively.

Referring to FIG. 6, the first inorganic layer EN1 may be formed on the light-emitting element OLED disposed on the substrate SUB (S100).

The first electrode EL1, the light-emitting layer OL, and the second electrode EL2 may be sequentially formed on the substrate SUB. Accordingly, the light-emitting element OLED may be formed on the substrate SUB.

In an embodiment, each of the first electrode EL1 and the second electrode EL2 may be formed through a deposition process. In an embodiment, for example, each of the first electrode EL1 and the second electrode EL2 may include or be formed of a conductive material.

In an embodiment, the light-emitting layer OL may be formed through an inkjet process. In an embodiment, for example, the light-emitting layer OL may be formed of an organic light-emitting material. In an embodiment, the light-emitting layer OL may have a multi-layer structure including various functional layers. In an embodiment, for example, the light-emitting layer OL may have a structure in which a hole injection layer (HIL), a hole transport layer (HTL), an electron transport layer (ETL), and an electron injection layer (EIL) are sequentially stacked.

Next, the first inorganic layer EN1 may be formed on the light-emitting element OLED. In an embodiment, the first inorganic layer EN1 may be formed through a chemical vapor deposition (CVD) process. In an embodiment, the first inorganic layer EN1 may include or be formed of silicon oxynitride (SiON).

Referring to FIG. 7, the organic layer EN2 may be formed on the first inorganic layer EN1 (S200).

In an embodiment, the organic layer EN2 may be formed through the inkjet process. In an embodiment, the organic layer EN2 may include or be formed of the monomer.

In an embodiment, an ashing process may be performed after the forming of the organic layer EN2. A portion of the organic layer EN2 formed in the peripheral area (e.g., the peripheral area PA of FIG. 1) may be removed through an ashing process, such that the organic layer EN2 having low moisture permeability may not be exposed to an outside of the display device (e.g., the display device DD of FIG. 1).

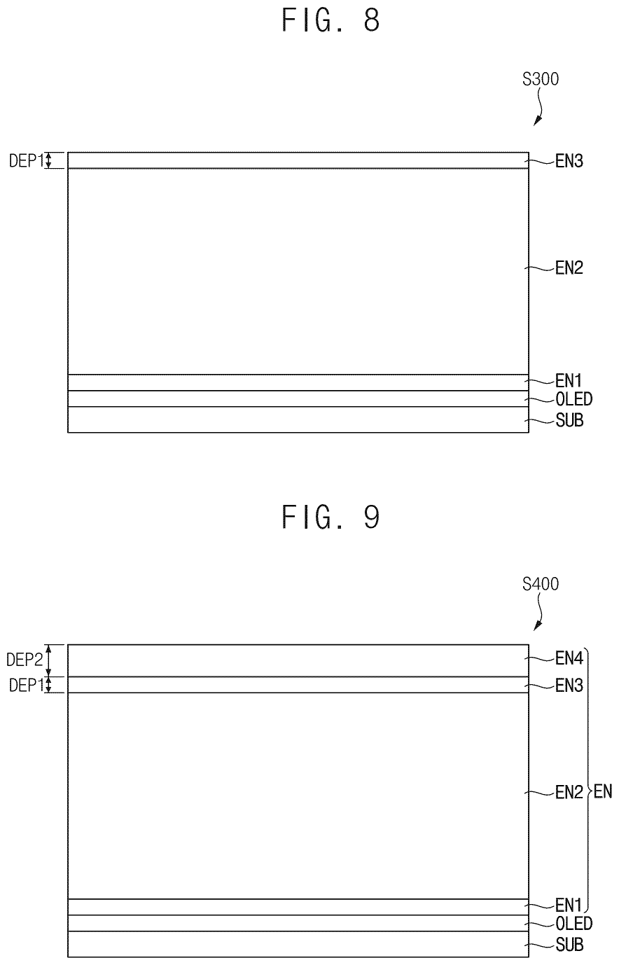

Referring to FIGS. 8 and 9, the second inorganic layer EN3 may be formed on the organic layer EN2 (S300). Next, the third inorganic layer EN4 may be formed on the second inorganic layer EN3 (S400).

In an embodiment, each of the second inorganic layer EN3 and the third inorganic layer EN4 may be formed through the chemical vapor deposition (CVD) process.

In an embodiment, each of the second inorganic layer EN3 and the third inorganic layer EN4 may include or be formed of a same material as each other. In an embodiment, each of the second inorganic layer EN3 and the third inorganic layer EN4 may include or be formed of silicon nitride (SiN).

In an embodiment, the process conditions may be set so that the second inorganic layer EN3 may have the barrier characteristics without any plasma damage to the organic layer EN2.

In an embodiment, to form the second inorganic layer EN3, the internal pressure of the chamber CH may be in a range of about 1 torr to about 1.7 torr, and the RF power may be in a range of about 3000 W to about 5000 W. Accordingly, the plasma damage might not be formed on the organic layer EN2. In addition, a mean free path of plasma ions may be increased, reactivity may be increased, and the grain size of the silicon nitride may be reduced, thereby reducing the voids in the film. Through this, the dense film having improved quality may be formed.

In an embodiment, the second thickness DEP2 of the third inorganic layer EN4 may be formed differently from the first thickness DEP1 of the second inorganic layer EN3. In an embodiment, the second thickness DEP2 of the third inorganic layer EN4 having the barrier characteristics may be formed to be the largest. In an embodiment, for example, the first thickness DEP1 of the second inorganic layer EN3 may be in a range of about 300 À and about 1000 Å, and the second thickness DEP2 of the third inorganic layer may be in a range of about 6000 Å and about 10000 Å. Accordingly, the light-emitting element OLED may be protected from external moisture or oxygen.

After the ashing process, the top surface of the organic layer EN2 might not be flat. Accordingly, when the second inorganic layer EN3 is deposited on the organic layer EN2, step coverage may be reduced. Next, when the third inorganic layer EN4 is deposited on the second inorganic layer EN3, the step coverage may be further reduced. Accordingly, a fine seam may occur in a portion where the step coverage is further reduced. The moisture or the oxygen may flow into the gap.

The display device according to an embodiment of the disclosure (e.g., the display device DD of FIG. 1) may include the encapsulation layer EN. The encapsulation layer EN may have the structure in which the first inorganic layer EN1, the organic layer EN2, the second inorganic layer EN3, and the third inorganic layer EN4 are sequentially stacked. The film density of the second inorganic layer EN3 included in the encapsulation layer EN may be in a range of about 1.7 g/cm³ to about 1.9 g/cm³. Accordingly, the second inorganic layer EN3 may become a dense film having the barrier properties. In addition, the refractive index of the second inorganic layer EN3 may be in a range of about 1.85 to about 1.86. Accordingly, the second inorganic layer EN3 may transmit the light emitted from the light-emitting element OLED without absorbing the light incident thereto. Therefore, the barrier characteristics of the display device may be further enhanced without a substantial change in the display quality.

The display device according to embodiments may be applied to a computer, a notebook, a mobile phone, a smartphone, a smart pad, a personal media player (PMP), a personal digital assistant (PDA), an MP3 player, or the like. In addition, the method of manufacturing the display device according to embodiments may be applied to a manufacturing process of the computer, the notebook, the mobile phone, the smartphone, the smart pad, the PMP, the PDA, the MP3 player, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a light-emitting layer disposed on the substrate;
a first inorganic layer disposed on the light-emitting layer;
an organic layer disposed on the first inorganic layer;
a second inorganic layer disposed on the organic layer, wherein the second inorganic layer has a film density of about 1.7 grams per cubic centimeter (g/cm³) or greater and about 9 grams per cubic centimeter (g/cm³) or less, and a refractive index of about 1.85 or greater and about 1.86 or less; and
a third inorganic layer disposed on the second inorganic layer.

2. The display device of claim 1, wherein the second inorganic layer and the third inorganic layer have different thicknesses from each other.

3. The display device of claim 2, wherein the second inorganic layer has a thickness of about 300 angstroms (Å) or greater and about 1000 angstroms (Å) or less.

4. The display device of claim 2, wherein the third inorganic layer has a thickness of about 6000 angstroms (Å) or greater and about 10000 angstroms (Å) or less.

5. The display device of claim 1, wherein the second inorganic layer and the third inorganic layer include a same material as each other.

6. The display device of claim 5, wherein each of the second inorganic layer and the third inorganic layer includes silicon nitride.

7. The display device of claim 1, wherein each of the second inorganic layer and the third inorganic layer includes silicon oxynitride.

8. The display device of claim 1, further comprising:
a first active pattern disposed on the substrate; and
a second active pattern disposed on the first active pattern.

9. The display device of claim 8, wherein,
the first active pattern includes a silicon semiconductor, and
the second active pattern includes an oxide semiconductor.

10. A method of manufacturing a display device, the method comprising:
forming a light-emitting layer on a substrate;
forming a first inorganic layer on the light-emitting layer;
forming an organic layer on the first inorganic layer;
forming a second inorganic layer on the organic layer, wherein the second inorganic layer has a film density of about 1.7 grams per cubic centimeter (g/cm³) or greater and about 1.9 grams per cubic centimeter (g/cm³) or less, and a refractive index of about 1.85 or greater and about 1.86 or less; and
forming a third inorganic layer on the second inorganic layer.

11. The method of claim 10, wherein each of the first inorganic layer, the second inorganic layer, and the third inorganic layer is formed by a chemical vapor deposition.

12. The method of claim 11, wherein plasma power to form the second inorganic layer is about 3000 watts (W) or greater and about 5000 watts (W) or less.

13. The method of claim 11, wherein a pressure of a chamber to form the second inorganic layer is about 1 torr or greater and about 1.7 torr or less.

14. The method of claim 10, wherein the organic layer is formed by an inkjet process.

15. The method of claim 10, wherein the second inorganic layer and the third inorganic layer are formed to have different thicknesses from each other.

16. The method of claim 15, wherein the second inorganic layer is formed to have a thickness of about 300 angstroms (Å) or greater and about 1000 angstroms (Å) or less.

17. The method of claim 15, wherein the third inorganic layer is formed to have a thickness of about 6000 angstroms (Å) or greater and about 10000 angstroms (Å) or less.

18. The method of claim 10, wherein the second inorganic layer and the third inorganic layer include a same material as each other.

19. The method of claim 18, wherein each of the second inorganic layer and the third inorganic layer includes silicon nitride.

20. The method of claim 10, wherein each of the second inorganic layer and the third inorganic layer includes silicon oxynitride.
